(19) United States
(12) Patent Application Publication
(10) Pub. No.: US 2024/0292726 A1
(43) Pub. Date: Aug. 29, 2024

(54) METHOD OF MANUFACTURING QLED DEVICE, QLED DEVICE, AND DISPLAY DEVICE

(71) Applicant: TCL Technology Group Corporation, Huizhou, Guangdong (CN)

(72) Inventor: Zhenlei YAO, Huizhou, Guangdong (CN)

(73) Assignee: TCL Technology Group Corporation, Huizhou, Guangdong (CN)

(21) Appl. No.: 18/570,139

(22) PCT Filed: Aug. 26, 2022
(86) PCT No.: PCT/CN2022/115210

§ 371 Date: Dec. 14, 2023

(30) Foreign Application Priority Data
Aug. 27, 2021 (CN) 202110998269.3

(51) Int. Cl. H10K 71/12; C09K 11/06; H10K 50/115; H10K 50/15; H10K 50/16; H10K 85/10; H10K 85/60

(52) U.S. Cl. CPC H10K 71/12; C09K 11/06; H10K 50/115; H10K 50/15; H10K 50/16; C09K 2211/10; H10K 85/1135; H10K 85/60

(57) ABSTRACT

A method of manufacturing an QLED device incudes: providing a substrate having a quantum dot layer on an anode; applying an oxidizing agent solution on the quantum dot layer; forming an electron transport layer on the quantum dot layer; and forming a cathode on the electron transport layer to obtain the QLED device. Material of the quantum dot layer includes a quantum dot, an unsaturated fatty acid ligand is bonded to a surface of the quantum dot, and material of the electron transport layer includes a n-type nano-metal oxide.

This application claims priority to Chinese Patent Application No. 202110998269.3, filed in the China National Intellectual Property Administration on Aug. 27, 2021, and entitled “METHOD OF MANUFACTURING QLED DEVICE, QLED DEVICE, AND DISPLAY DEVICE”, which is incorporated herein by reference in its entirety.

### TECHNICAL FIELD

The present disclosure relates to a field of display technologies, and more particularly, to a method for manufacturing a QLED device, a QLED device, and a display device.

### BACKGROUND

Quantum dot light emitting diodes (QLED) based on semiconductor quantum dots exhibit broad application prospects in the fields of display and illumination due to the advantages of better monochromaticity, color saturation, and lower manufacturing cost.

A light-emitting layer of the QLED device has quantum dots. Since quantum dots are generally inorganic nanocrystals, in order to improve the solubility of the quantum dot nanocrystals in solution, many organic ligands are typically bonded to the surface of the quantum dots. The organic ligands commonly used are unsaturated fatty acids. However, after the quantum dots are formed into a film, the quantum dots with ligands may increase the injection barrier of electrons, so that the operating voltage of the device is increased, and an unnecessary thermal effect is generated, resulting in degradation of the performance of the device.

### SUMMARY

### Technical Problem

Therefore, how to reduce the electron injection barrier of the QLED to improve the performance of the QLED device is a technical problem to be solved by the present disclosure.

### Solution to Technical Problem

### Technical Solution

In view of this, the present disclosure provides a method for manufacturing a QLED device, a QLED device, and a display device to reduce an electron injection barrier of the QLED, thereby improving performance of the QLED device.

In a first aspect, the present disclosure provides a method of manufacturing a QLED device, including the steps of:
providing a substrate having a quantum dot layer on an anode;
applying an oxidizing agent solution on the quantum dot layer;
forming an electron transport layer on the quantum dot layer; and
forming a cathode on the electron transport layer to obtain the QLED device,
material of the quantum dot layer includes a quantum dot, an unsaturated fatty acid ligand is bonded to a surface of the quantum dot, and material of the electron transport layer includes a n-type nano-metal oxide.

Alternatively, the oxidizing agent solution includes an oxidizing agent, a catalyst, and an ultra-dry organic solvent.

Alternatively, the oxidizing agent is selected from peroxyorganic acids.

The catalyst is selected from at least one of copper chloride, zinc chloride, or aluminum chloride;

The ultra-dry organic solvent is selected from ultra-dry ethanol.

Alternatively, the peroxyorganic acid is selected from at least one of m-chloroperoxybenzoic acid, trifluoroperoxyacetic acid, monoperoxymaleic acid, monoperoxyphthalic acid, 3,5-dinitroperoxybenzoic acid, p-nitroperoxybenzoic acid, peroxyformic acid, or peroxybenzoic acid.

Alternatively, the unsaturated fatty acid ligand is oleic acid.

Alternatively, the material of the n-type nano-metal oxide includes at least one of zinc oxide, titanium dioxide, magnesium oxide, or aluminum oxide.

Alternatively, a concentration of the oxidizing agent ranges from 10 mg/mL to 50 mg/mL, and a concentration of the catalyst ranges from 10 mg/mL to 30 mg/mL.

Alternatively, the step of applying the oxidizing agent solution on the quantum dot layer includes: applying the oxidizing agent solution on the quantum dot layer until the oxidizing agent solution completely covers a surface of the quantum dot layer, and cleaning remaining reactants on the surface of the quantum dot layer after an oxidation reaction is completed.

Alternatively, in the oxidation reaction, time of the oxidation reaction ranges from 20 min to 40 min.

Alternatively, the step of providing the substrate having the quantum dot layer on the anode includes: applying a quantum dot solution on the anode by a solution method, and forming the quantum dot layer after heat treatment, the quantum dot solution includes a quantum dot and a non-polar solvent.

In a second aspect, the present disclosure provides an QLED device including an anode, a cathode, and a stacked layer disposed between the cathode and the anode, the stacked layer includes a quantum dot layer and an electron transport layer, the quantum dot layer is disposed close to the anode, the electron transport layer is disposed close to the cathode, material of the electron transport layer includes a n-type nano-metal oxide, material of the quantum dot layer includes a quantum dot, and there is a quantum dot bonded to a dicarboxylic acid ligand at an interface between the quantum dot layer and the electron transport layer.

Alternatively, the dicarboxylic acid ligand is azelaic acid.

Alternatively, material of the n-type nano-metal oxide includes at least one of zinc oxide, titanium dioxide, magnesium oxide, or aluminum oxide.

Alternatively, material of the quantum dot includes at least one of a group II-VI compound, a group III-V compound, or a group I-III-VI compound; the group II-VI compound is selected from at least one of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, or CdZnSTe; the group III-V compound is selected from at least one of InP, InAs, GaP, GaAs, GaSb, AlN, AlP, InAsP, InNP, InNSb, GaAINP, or InAlNP; the group I-III-VI compound is selected from at least one of CuInS₂, CuInSe₂, or AgInS₂.

Alternatively, at the interface between the quantum dot layer and the electron transport layer, a mass percentage of the quantum dot bonded to the dicarboxylic acid ligand ranges from 80% to 90% based on a total weight of the material of the quantum dot layer.

Alternatively, the QLED device further includes a hole transport layer disposed between the anode and the quantum dot layer.

The material of the hole transport layer is selected from poly(9,9-dioctylfluorene-CO—N-(4-butylphenyl)diphenylamine), poly(3-hexylthiophene), poly(9-vinylcarbazole), poly[bis(4-phenyl)(4-butylphenyl)amine], 4,4′,4′-tris(carbazol-9-yl)triphenylamine, or 4,4′-bis(9-carbazolyl)biphenyl.

In a third aspect, the present disclosure provides a display device including a QLED device manufactured by a method of manufacturing the QLED device, the method of manufacturing the QLED device including the steps of:
providing a substrate having a quantum dot layer on an anode;
applying an oxidizing agent solution on the quantum dot layer;
forming an electron transport layer on the quantum dot layer; and
forming a cathode on the electron transport layer to obtain the QLED device, and
material of the quantum dot layer includes a quantum dot, an unsaturated fatty acid ligand is bonded to a surface of the quantum dot, material of the electron transport layer includes a n-type nano-metal oxide, and there is a quantum dot bonded to a dicarboxylic acid ligand at an interface between the quantum dot layer and the electron transport layer.

Alternatively, the oxidizing agent solution includes an oxidizing agent, a catalyst, and an ultra-dry organic solvent.

The oxidizing agent is selected from peroxyorganic acids; the catalyst is selected from at least one of copper chloride, zinc chloride, or aluminum chloride; and the ultra-dry organic solvent is selected from ultra-dry ethanol.

Alternatively, the peroxyorganic acid is selected from at least one of m-chloroperoxybenzoic acid, trifluoroperoxyacetic acid, monoperoxymaleic acid, monoperoxyphthalic acid, 3,5-dinitroperoxybenzoic acid, p-nitroperoxybenzoic acid, peroxyformic acid, or peroxybenzoic acid.

Alternatively, the dicarboxylic acid ligand is azelaic acid.

### Advantages of Invention

### Beneficial Effect

The present disclosure provides a method for manufacturing a QLED device, in which an unsaturated fatty acid ligand is broken at an unsaturated double bond of the unsaturated fatty acid ligand by an oxidizing reaction using an oxidizing agent solution to generate a short-chain acid, so that the ligand on the surface of a quantum dot is changed from the unsaturated fatty acid to a dicarboxylic acid. Since the dicarboxylic acid has two polar functional groups, one side of the dicarboxylic acid may be connected to the quantum dot through a coordination bond, and the other side of the dicarboxylic acid may be connected to the n-type nano-metal oxide in the electron transport layer, thereby shortening the distance between the quantum dot light-emitting layer and the electron transport layer, effectively increasing the electron injection rate, and further improving the device performance.

### BRIEF DESCRIPTION OF FIGURES

### Description of Drawings

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

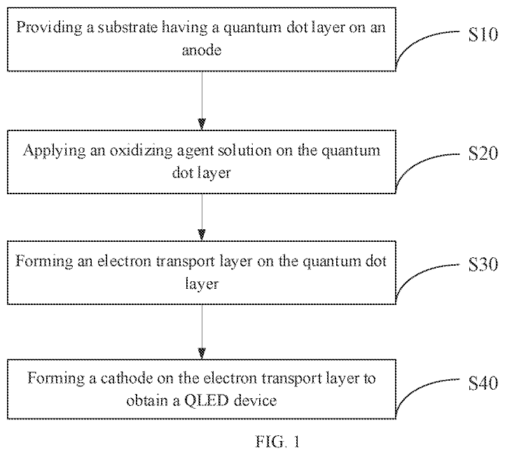

FIG. 1 is a schematic flow diagram of an embodiment of a method of manufacturing a QLED device according to an embodiment of the present disclosure;

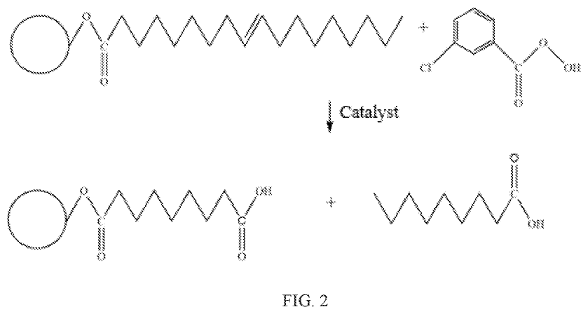

FIG. 2 is a schematic diagram of an embodiment of an oxidation reaction of a quantum dot surface ligand of a QLED device according to an embodiment of the present disclosure; and

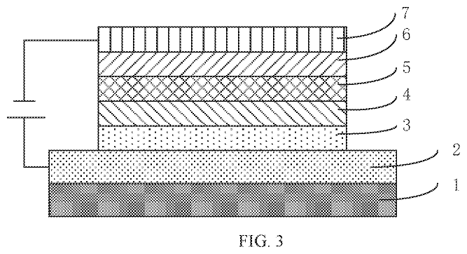

FIG. 3 is a schematic structural diagram of an embodiment of a QLED device according to an embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Embodiments of the present disclosure provide a method for manufacturing a QLED device, a QLED device, and a display device. Detailed descriptions are given below. It should be noted that the order in which the following embodiments are described is not intended to limit the preferred order of the embodiments.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure; Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

Firstly, as shown in FIG. 1, an embodiment of the present disclosure provides a method for manufacturing a QLED device, which specifically includes the following steps.

At S10, a substrate having a quantum dot layer on an anode is provided.

At S20, an oxidizing agent solution is applied on the quantum dot layer.

At S30, an electron transport layer is formed on the quantum dot layer.

At S40, a cathode is formed on the electron transport layer to obtain a QLED device.

The material of the quantum dot layer includes a quantum dot to which an unsaturated fatty acid ligand is bonded, and the material of the electron transport layer includes n-type nano-metal oxide, and the oxidizing agent solution includes an oxidizing agent, a catalyst, and an ultra-dry organic solvent.

The commonality of quantum dot materials is that there a large number of defects on the surface, for example: non-bonded cations, which are the main factors of low quantum efficiency of quantum dots. The ligand may provide electrons, the surface of quantum dot provides empty orbits for non-bonded cations, the ligands and the non-bonded cations are bonded by means of coordination, which serves the purpose of passivating quantum dot defects and preventing the efficiency of the quantum dots from decreasing. Common organic ligands are unsaturated fatty acids, however, applicants have found that after quantum dot film formation, the unsaturated fatty acid ligands with long carbon chains may block the contact between the quantum dot layer and the electron transport layer, which increases the electron injection barrier, increases the operating voltage of the device, causes unnecessary thermal effects, and leads to a decrease in device performance.

The present disclosure therefore provides a method for manufacturing a QLED device, in which an unsaturated fatty acid ligand is chain-broken at an unsaturated double bond of the unsaturated fatty acid ligand by an oxidation reaction to form a short-chain acid, without affecting the properties of the quantum dot itself. In this way the ligand on the surface of the quantum dot changes from unsaturated fatty acids to dicarboxylic acids. The dicarboxylic acid has two polar functional groups, and since a metal atom in the n-type nano-metal oxide has an empty orbit and an oxygen atom in the two polar functional groups of azelaic acid has a lone pair of electrons, coordination bonds are easily formed between the metal atom and the azelaic acid. Therefore, one of the two polar functional groups of azelaic acid may be connected to the quantum dot by a coordination bond, and the other may be connected to the n-type nano-metal oxide in the electron transport layer, so that the distance between the quantum dot light-emitting layer and the electron transport layer may be shorten, thereby increasing the electron injection rate and improving the device performance.

In some embodiments, the unsaturated fatty acid may be an unsaturated fatty acid with 8 to 18 carbon atoms, and the unsaturated fatty acid may be linear or branched, for example, tetradecenoic acid, hexadecenoic acid or above enoic acid containing branched chains. But not limited thereto, in an embodiment, the unsaturated fatty acid ligand is oleic acid. The oleic acid is an octadecenoic acid, and is an unsaturated fatty acid ligand commonly used for quantum dots. The oleic acid is easily oxidized and broken at a double bond between the ninth carbon and the tenth carbon. The oxidation method provided in the present disclosure may convert the oleic acid ligand on the surface of the quantum dots into an azelaic acid ligand.

For example, as shown in FIG. 2, FIG. 2 is a schematic diagram of an embodiment in which a ligand on the surface of a quantum dot undergoes an oxidation reaction. Under the action of a catalyst, the oleic acid is reacted with m-chloroperoxybenzoic acid, and the oleic acid is oxidized and broken at the double bond between the ninth carbon and the tenth carbon to form the azelaic acid. The azelaic acid has a linear-chain structure, each of two ends of the linear-chain structure has a carboxylic acid, the carboxylic acid at one end of the linear-chain structure is connected to the quantum dot, and the carboxylic acid at another end of the linear-chain structure is connected to the n-type nano-metal oxide, so that the distance between the quantum dot light-emitting layer and the electron transport layer may be shorten, thereby increasing the electron injection rate and improving the device performance.

In the present disclosure, a dicarboxylic acid ligand is generated through an oxidation reaction, which avoids re-introduction of a dicarboxylic acid in an original quantum dot preparation system, can sufficiently retain an unsaturated fatty acid ligand left by an original unsaturated fatty acid reaction system, avoids directly adding the dicarboxylic acid as a ligand to the reaction system to affect the preparation of a quantum dot, reduces the influence of the strong polarity of the dicarboxylic acid on the solubility of the quantum dot in a solvent such as n-octane, and reduces the influence of the ligand type on the quantum dot layer processing process.

Taking the oleic acid ligand as an example, in the process of preparing the quantum dots, the precursor for the synthesis of quantum dots is cadmium oleate, and the solvent is oleic acid, so that the surface ligand of the quantum dots is naturally oleic acid, and the direct combination of azelaic acid and the quantum dots does not favor the whole reaction system. Further, if the surface ligand of the quantum dot is directly exchanged from oleic acid to azelaic acid, the polarity of the ligand after the ligand exchange is greatly changed, and the azelaic acid has a strong polarity, which affects the solubility of the quantum dot in the solvent, therefore, it is not suitable for the solution system used in the device manufacturing process. In the present disclosure, the quantum dot layer containing the unsaturated carboxylic acid ligand is formed first, and then an oxidation treatment is performed on the surface of the quantum dot, so as to reduce the effect on the device.

In some embodiments, the oxidizing agent solution includes an oxidizing agent, a catalyst, and an ultra-dry organic solvent.

In some embodiments, the oxidizing agent is selected from peroxyorganic acids, which may be selected from at least one of m-chloroperoxybenzoic acid, trifluoroperoxyacetic acid, monoperoxymaleic acid, monoperoxyphthalic acid, 3,5-dinitroperoxybenzoic acid, p-nitroperoxybenzoic acid, peroxyformic acid, or peroxybenzoic acid. The peroxidized organic acid is less acidic and therefore a mild oxidation reaction may occur on the surface of the quantum dot layer to break the unsaturated fatty acid ligand at its unsaturated double bond without affecting the properties of the quantum dot itself. But the present disclosure is not limited thereto, the oxidizing agent may also be selected from other weak acids, such as peroxy mineral acid compounds, as long as the unsaturated fatty acid ligand on the quantum dots may be chain-broken at its unsaturated double bond, and it is not specifically limited herein.

In some embodiments, the catalyst may be selected from at least one of copper chloride (CuCl₂), zinc chloride (ZnCl₂), or aluminum chloride (AlCl₃).

The purpose of the ultra-dry organic solvent is to dissolve the oxidizing agent and the catalyst. On the other hand, its purpose is to reduce the erosion of the moisture to the quantum dots, and prevent the moisture and the catalyst such as copper chloride from generating HCl and causing damage to the quantum dots. In a particular embodiment, the ultra-dry organic solvent may be selected from ultra-dry ethanol.

In some embodiments, the concentration of the oxidizing agent ranges from 10 mg/mL (milligrams per milliliter) to 50 mg/mL. If the concentration of the oxidizing agent is too high, a side reaction such as detachment of the ligand from the surface of the quantum dot may be caused. If the concentration of the oxidizing agent is too low, a slow reaction or even non-reaction may be caused, and the device manufacturing period becomes longer, which is unfavorable for production. It may be appreciated that the concentration of the oxidizing agent may be any value within 10 mg/mL to 50 mg/mL, e.g., 10 mg/mL, 15 mg/mL, 20 mg/mL, 25 mg/mL, 30 mg/mL, 35 mg/mL, 40 mg/mL, 45 mg/mL, 50 mg/mL, etc.

In some embodiments, the concentration of the catalyst ranges from 10 mg/mL to 30 mg/mL. If the concentration of the catalyst is too high, excessive adsorption of the catalyst on the surface of the quantum dots may be caused, and the cleaning difficulty in the subsequent cleaning process may be increased. If the concentration of the catalyst is too low, slow reaction or even non-reaction may be caused, and the device manufacturing period becomes longer, which is unfavorable for production. It may be appreciated that the concentration of the catalyst may be any value within 10 mg/mL to 30 mg/mL, such as 10 mg/mL, 12 mg/mL, 15 mg/mL, 18 mg/mL, 20 mg/mL, 22 mg/mL, 25 mg/mL, 27 mg/mL, 30 mg/mL, etc.

In some embodiments, applying an oxidizing agent solution on the quantum dot layer includes: applying the oxidizing agent solution on the quantum dot layer until the oxidizing agent solution completely covers the surface of the quantum dot layer, and cleaning remaining reactants on the surface of the quantum dot layer after the oxidation reaction is completed.

In some embodiments, in the oxidation reaction, the time of the oxidation reaction ranges from 20 min (minute) to 40 min. If the reaction time is too long, the device manufacturing period becomes longer, which is unfavorable to the production. If the reaction time is too short, the reaction is incomplete, which affects the performance of the device. It may be appreciated that the reaction time may take any value within 20 min to 40 min, e.g., 20 min, 22 min, 25 min, 27 min, 30 min, 32 min, 35 min, 37 min, 40 min, etc.

In some embodiments, during the cleaning of the remaining reactants on the surface of the quantum dot layer, the cleaning solution utilized is an ultra-dry organic solution, such as ultra-dry ethanol, to reduce erosion of the quantum dots by moisture.

In embodiments of the present disclosure, the functional layers of the QLED device may be formed by methods known in the art, such as a solution method, which may include a spin coating method, a press method, an inkjet printing method, a scrape coating method, a printing method, a dip-coating method, a immersion method, a spray coating method, a roll coating method, a casting method, a slit coating method, and a strip coating method.

For example, when each of the functional layers is formed using the solution method, the manufacturing of the QLED device includes the following steps.

At S11, a quantum dot solution is applied on the anode by the solution method, and a quantum dot layer is formed after heat treatment, wherein the quantum dot solution includes quantum dots and a non-polar solvent.

At S21, an oxidizing agent solution is applied on the quantum dot layer.

At S31, an electron transport layer is applied on the quantum dot layer by the solution method.

At S41, a cathode is deposited on the electron transport layer to obtain a QLED device.

The non-polar solvent may be a non-polar solvent known in the art for dissolving quantum dots, such as n-octane, toluene, benzene, cyclohexane, and the like. In the present disclosure, a dicarboxylic acid ligand is generated through an oxidation reaction, which avoids re-introduction of the dicarboxylic acid in the original quantum dot preparation system, can reduce the influence of the strong polarity of the dicarboxylic acid on the solubility of the quantum dots in a solvent, particularly a non-polar solvent, and reduces the influence of the ligand type on the light-emitting layer processing process.

When the solution method is specifically the spin coating method, since the spin coating method has the characteristics of mild process conditions, simple operation, energy saving, environmental protection, and the like, the photovoltaic device manufactured by the method has the advantages of high mobility of carriers (i.e., holes or electrons), accurate thickness, and the like.

For example, when each of the functional layers is formed by the spin coating method, the manufacturing of the QLED device includes the following steps.

At S111, a quantum dot layer is spin-coated on an anode.

At S211, an oxidizing agent solution is applied on the quantum dot layer.

At S311, an electron transport layer is spin-coated on the quantum dot layer.

At S411, a cathode is deposited on the electron transport layer to obtain a QLED device.

The anode of the QLED device according to the embodiment of the present invention is formed on a substrate, and a hole functional layer, such as a hole transport layer, a hole injection layer, and an electron blocking layer, may be formed between the anode and the quantum dot layer. An electron functional layer, such as an electron injection layer and a hole blocking layer, may be formed between the cathode and the quantum dot layer.

In various embodiments of the present disclosure, the material of each of the functional layers is common material in the art.

For example, the substrate may be a rigid substrate or a flexible substrate. Specifically, it may be a glass substrate.

The anode may be ITO or FTO.

The material of the hole transport layer may be selected from, but not limited to, TFB (poly(9,9-dioctylfluorene-CO—N-(4-butylphenyl)diphenylamine)), P₃HT (poly(3-hexylthiophene)), PVK (poly(9-vinylcarbazole)), poly-TPD (poly[bis(4-phenyl)(4-butylphenyl)amine]), TCTA (4,4′,4′-tris(carbazol-9-yl)triphenylamine), CBP (4,4′-bis(9-carbazol)biphenyl), or the like.

The quantum dot may be selected from, but not limited to, at least one of a group II-VI compound, a group III-V compound, or a group I-III-VI compound. The group II-VI compound may be selected from at least one of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, or CdZnSTe. The group III-V compound may be selected from at least one of InP, InAs, GaP, GaAs, GaSb, AlN, AlP, InAsP, InNP, InNSb, GaAINP, or InAlNP. The group I-III-VI compound may be selected from at least one of CuInS₂, CuInSe₂ and AgInS₂.

The N-type nano-metal oxide may be selected from, but not limited to, at least one of zinc oxide, titanium dioxide, magnesium oxide, aluminum oxide, and oxides of alloys of the foregoing metals.

In some embodiments, the quantum dot layer material consists of quantum dots to which unsaturated fatty acid ligands are bound; and/or the material of the electron transport layer consists of the n-type nano-metal oxide; and/or the oxidizing agent solution consists of the oxidizing agent, the catalyst and the ultra-dry organic solvent.

The cathode may be a metal material, such as aluminum elementary material, magnesium elementary material, calcium elementary material, silver elementary material, or an alloy material thereof, or the like.

The present disclosure also provides a QLED device including an anode, a cathode, and a stacked layer disposed between the cathode and the anode. The stacked layer includes a quantum dot layer and an electron transport layer, the quantum dot layer is disposed close to the anode, and the electron transport layer is disposed close to the cathode. The material of the electron transport layer includes a n-type nano-metal oxide, the material of the quantum dot layer includes quantum dots, the surface of the quantum dot is bonded with a ligand, at least a portion of the ligands are dicarboxylic acid ligands, the dicarboxylic acid ligands and quantum dots bonded with the dicarboxylic acid ligands are distributed at an interface where the quantum dot layer and the electron transport layer contact each other.

According to the QLED device provided in the embodiment of the present disclosure, the ligand on the surface of the quantum dot is the dicarboxylic acid having the two polar functional groups. Since a metal atom in the n-type nano-metal oxide has an empty orbit and an oxygen atom in the two polar functional groups of azelaic acid has a lone pair of electrons, coordination bonds are easily formed between the metal atom and the azelaic acid. The dicarboxylic acid ligands and quantum dots bonded with the dicarboxylic acid ligands are distributed at an interface where the quantum dot layer and the electron transport layer contact each other, so that one of the two polar functional groups of azelaic acid may be connected to the quantum dot through the coordination bonds, and the other may be connected to the n-type nano-metal oxide in the electron transport layer. Therefore, the distance between the quantum dot light-emitting layer and the electron transport layer may be shorten, thereby increasing the electron injection rate and improving the device performance.

In the present disclosure, the dicarboxylic acid ligands and quantum dots bonded with the dicarboxylic acid ligands are distributed at an interface where the quantum dot layer and the electron transport layer contact each other. If the dicarboxylic acid ligands are distributed inside the quantum dot layer, the dicarboxylic acid has a strong polarity, which affects the solubility of the quantum dots in the solvent, therefore, it is not suitable for the solution system used in the device manufacturing process. In addition, the dicarboxylic acid ligand connected to the quantum dot is generally a short-chain acid having a number of carbon atoms of, for example, 4 to 9, so that the spacing between the quantum dots is generally small, and the energy between the quantum dots is easily transferred, which may be detrimental to the performance of the device. In the present disclosure, the ligand bonded to the quantum dot on the surface of the quantum dot layer is the dicarboxylic acid, and the ligand bonded to the quantum dot inside the quantum dot layer may be another long-chain ligand. The dicarboxylic acid on the surface may promote electron injection, and other internal long-chain ligands may reduce the energy transfer within the quantum dot film and the effect of solvents in the quantum dot processing system, which may further reduce the impact on the device.

In some embodiments, the dicarboxylic acid ligand is azelaic acid.

In some embodiments, at the interface between the quantum dot layer and the electron transport layer, the mass percentage of quantum dots bonded to the dicarboxylic acid ligands ranges from 80% to 90% based on the total weight of the quantum dot layer material at the interface.

For example, FIG. 3 shows a schematic structural diagram of an embodiment of a QLED device of the present disclosure. As shown in FIG. 3, the QLED device includes a substrate 1, an anode 2, a hole injection layer 3, a hole transport layer 4, a quantum dot layer 5, an electron transport layer 6, and a cathode 7 from bottom to top. The material of the substrate 1 is a glass substrate, the material of the anode 2 is an ITO substrate, the hole injection layer 3 includes PEDOT:PSS (poly(3,4-ethylenedioxy-thiophene)/polystyrene sulfonate) material, the material of the hole transport layer 4 is TFB, the material of the quantum dot layer 5 is quantum dot material to which the azelaic acid ligands are bonded, the material of the electron transport layer 6 is zinc oxide material, and the material of the cathode 7 is aluminum (Al).

On the basis of the above-described embodiments, the present disclosure further provides a display device including a QLED device manufactured by the manufacturing method described in any one of the above-described embodiments, or an QLED device described in any one of the above-described embodiments, a structure, implementation principles, and effects thereof are similar, and details are not described herein.

The QLED display device may be a lighting fixture and a backlight, or any product or component having a display function such as a mobile phone, a tablet computer, a television, a display, a notebook computer, a digital photo frame, and a navigator.

The present disclosure will now be described in detail by way of example.

### Example 1

This example provides a method for manufacturing a QLED device as follows.
(1) A PEDOT:PSS solution was added dropwise to an ITO glass substrate (i.e., an anode substrate including a substrate and an anode) and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An oxidizing agent solution was added dropwise to the quantum dot layer to ensure that the oxidizing agent solution covered the quantum dot film and reaction was carried out for 30 min, the oxidizing agent solution was composed of 20 mg/mL of m-chloroperoxybenzoic acid, 10 mg/mL of copper chloride and ultra-dry ethanol.
(5) After the reaction, the quantum dot thin film was cleaned using the ultra-dry ethanol.
(6) An electron transport layer was spin-coated on the cleaned quantum dot thin film.
(7) A cathode was deposited, and an encapsulation was performed.

### Example 2

This example provides a method for manufacturing a QLED device as follows.
(1) A PEDOT:PSS solution was added dropwise to an ITO glass substrate and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An oxidizing agent solution was added dropwise to the quantum dot layer to ensure that the oxidizing agent solution covered the quantum dot film and reaction was carried out for 40 min, the oxidizing agent solution was composed of 10 mg/mL of m-chloroperoxybenzoic acid, 10 mg/mL of copper chloride and ultra-dry ethanol.
(5) After the reaction, the quantum dot thin film was cleaned using the ultra-dry ethanol.
(6) An electron transport layer was spin-coated on the cleaned quantum dot thin film.
(7) A cathode was deposited, and an encapsulation was performed.

### Example 3

This example provides a method for manufacturing a QLED device as follows.
(1) A PEDOT:PSS solution was added dropwise to an ITO glass substrate and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An oxidizing agent solution was added dropwise to the quantum dot layer to ensure that the oxidizing agent solution covered the quantum dot film and reaction was carried out for 30 min, the oxidizing agent solution was composed of 30 mg/mL of m-chloroperoxybenzoic acid, 20 mg/mL of copper chloride and ultra-dry ethanol.
(5) After the reaction, the quantum dot thin film was cleaned using the ultra-dry ethanol.
(6) An electron transport layer was spin-coated on the cleaned quantum dot thin film.
(7) A cathode was deposited, and an encapsulation was performed.

### Example 4

This example provides a method for manufacturing a QLED device as follows.
(1) A PEDOT:PSS solution was added dropwise to an ITO glass substrate and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An oxidizing agent solution was added dropwise to the quantum dot layer to ensure that the oxidizing agent solution covered the quantum dot film and reaction was carried out for 20 min, the oxidizing agent solution was composed of 50 mg/mL of m-chloroperoxybenzoic acid, 30 mg/mL of copper chloride and ultra-dry ethanol.
(5) After the reaction, the quantum dot thin film was cleaned using the ultra-dry ethanol.
(6) An electron transport layer was spin-coated on the cleaned quantum dot thin film.
(7) A cathode was deposited, and an encapsulation was performed.

### Example 5

This example provides a method for manufacturing a QLED device as follows.
(1) A PEDOT:PSS solution was added dropwise to an ITO glass substrate and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An oxidizing agent solution was added dropwise to the quantum dot layer to ensure that the oxidizing agent solution covered the quantum dot film and reaction was carried out for 30 min, the oxidizing agent solution was composed of 20 mg/mL of trifluoroperacetic acid, 10 mg/mL of copper chloride and ultra-dry ethanol.
(5) After the reaction, the quantum dot thin film was cleaned using the ultra-dry ethanol.
(6) An electron transport layer was spin-coated on the cleaned quantum dot thin film.
(7) A cathode was deposited, and an encapsulation was performed.

### Example 6

This example provides a method for manufacturing a QLED device as follows.
(1) A PEDOT:PSS solution was added dropwise to an ITO glass substrate and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An oxidizing agent solution was added dropwise to the quantum dot layer to ensure that the oxidizing agent solution covered the quantum dot film and reaction was carried out for 30 min, the oxidizing agent solution was composed of 40 mg/mL of peroxybenzoic acid, 20 mg/mL of copper chloride and ultra-dry ethanol.
(5) After the reaction, the quantum dot thin film was cleaned using the ultra-dry ethanol.
(6) An electron transport layer was spin-coated on the cleaned quantum dot thin film.
(7) A cathode was deposited, and an encapsulation was performed.

### Comparison Example

The present comparison example provides a method for manufacturing a QLED device as follows.
(1) A PEDOT:PSS solution was added dropwise to an ITO glass substrate and spin-coated into a film to form a hole injection layer.
(2) A TFB solution was added dropwise to the hole injection layer and spin-coated into a film to form a hole transport layer.
(3) A quantum dot layer with oleic acid ligands was spin-coated on the hole transport layer.
(4) An electron transport layer was spin-coated on the cleaned quantum dot thin film.
(5) A cathode was deposited, and an encapsulation was performed.

### Verification Example

In order to illustrate the effects of oxidation treatment on the quantum dot layer according to the embodiments of present disclosure on the performance attenuation and quantum efficiency of the quantum dot device, a verification example is also provided, and the lifetime and efficiency of the quantum dot device prepared in Examples 1 to 6 and Comparison Example were respectively tested according to methods known in the art, and the results are shown in Table 1 and Table 2.

TABLE 1
Performance of Devices of Examples
1 to 6 and Comparison Example

| | Device EQE | Device lifetime T95@1000 nit |
|---|---|---|
| Example 1 | 22 | 25000 h |
| Example 2 | 19 | 26000 h |
| Example 3 | 21 | 20000 h |
| Example 4 | 18 | 18000 h |
| Example 5 | 20 | 19000 h |
| Example 6 | 21 | 23000 h |
| Comparison example | 15 | 10000 h |

Note:
EQE is external quantum efficiency; T95@1000 nit refers to a time required for the maximum luminance of the device to decay from1000 nit to 950 calculated based on Lmax and T95, and an acceleration factor is 1.7.

TABLE 2
Current density versus voltage of Examples
1 to 6 and Comparison Example

| | Current density | Current density | Current density |
|---|---|---|---|
| | @3 V | @4 V | @5 V |
| Example 1 | 0.5958 | 37.0578 | 128.4737 |
| Example 2 | 0.6472 | 37.4911 | 132.5174 |
| Example 3 | 1.2913 | 45.2095 | 147.428 |
| Example 4 | 1.1602 | 39.0724 | 127.7243 |
| Example 5 | 0.6574 | 32.8071 | 112.7107 |
| Example 6 | 0.6335 | 30.2061 | 108.5022 |
| Comparison | 0.5859 | 4.2771 | 11.095 |
| example | | | |

Note:
the current densities @3 V, @4 V, and @5 V refer to the current densities under the condition of 3 V, 4 V, and 5 V, respectively, in mA/cm².

It can be seen from Table 1 that the device performances of the oxidized QLED devices prepared by the preparation methods of Examples 1 to 6 are improved. It can be seen from Table 2 that the current densities of the oxidized devices of Examples 1-6 are also greatly improved compared to the comparison example. Thus, after the oxidation treatment of the quantum dot layer of the QLED device, an unsaturated fatty acid ligand on the surface is changed to a dicarboxylic acid ligand after the oxidation treatment, and the polar end formed by the oxidation reaction can interact with the n-type nano-metal oxide in the electron transport layer, thereby reducing the energy barrier between the quantum dot and the electron transport layer, which may reduce the barrier of electron injection, promoting electron injection, and further increasing the current density.

In summary, the present disclosure provides a method for preparing a QLED device, a QLED device, and a display device. Without affecting the properties of a quantum dot itself, an oxidizing agent solution including an oxidizing agent, a catalyst, and an ultra-dry organic solvent is used to break a chain of an unsaturated fatty acid ligand at an unsaturated double bond thereof to form a short-chain acid, and the ligand on the surface of the quantum dot is converted into a dicarboxylic acid from the unsaturated fatty acid. The dicarboxylic acid has two polar functional groups, one of the two polar functional groups of azelaic acid may be connected to the quantum dot through the coordination bonds, and the other may be connected to the n-type nano-metal oxide in the electron transport layer, so that the distance between the quantum dot light-emitting layer and the electron transport layer may be shorten, thereby increasing the electron injection rate and improving the device performance.

The QLED device, the QLED device, and the display device according to the embodiments of the present disclosure are described in detail, and the principles and embodiments of the present disclosure are described herein using specific examples. The description of the above embodiments is merely provided to help understand the method and the core idea of the present disclosure. At the same time, changes may be made by those skilled in the art to both the specific implementations and the scope of application in accordance with the teachings of the present disclosure. In view of the foregoing, the content of the present specification should not be construed as limiting the disclosure.

1. A method of manufacturing a QLED device, comprising steps of:
providing a substrate having a quantum dot layer on an anode;
applying an oxidizing agent solution on the quantum dot layer;
forming an electron transport layer on the quantum dot layer; and
forming a cathode on the electron transport layer to obtain the QLED device,
wherein material of the quantum dot layer comprises a quantum dot, an unsaturated fatty acid ligand is bonded to a surface of the quantum dot, and material of the electron transport layer comprises a n-type nano-metal oxide.

2. The method according to claim 1, wherein the oxidizing agent solution comprises an oxidizing agent, a catalyst, and an ultra-dry organic solvent.

3. The method according to claim 2, wherein the oxidizing agent is selected from peroxyorganic acids;
the catalyst is selected from at least one of copper chloride, zinc chloride, or aluminum chloride; and
the ultra-dry organic solvent is selected from ultra-dry ethanol.

4. The method according to claim 3, wherein the peroxyorganic acid is selected from at least one of m-chloroperoxybenzoic acid, trifluoroperoxyacetic acid, monoperoxymaleic acid, monoperoxyphthalic acid, 3,5-dinitroperoxybenzoic acid, p-nitroperoxybenzoic acid, peroxyformic acid, or peroxybenzoic acid.

5. The method according to claim 1, wherein the unsaturated fatty acid ligand is oleic acid.

6. The method according to claim 1, wherein material of the n-type nano-metal oxide comprises at least one of zinc oxide, titanium dioxide, magnesium oxide, or aluminum oxide.

7. The method according to claim 2, wherein a concentration of the oxidizing agent ranges from 10 mg/mL to 50 mg/mL, and a concentration of the catalyst ranges from 10 mg/mL to 30 mg/mL.

8. The method according to claim 2, wherein the step of applying the oxidizing agent solution on the quantum dot layer comprises: applying the oxidizing agent solution on the quantum dot layer until the oxidizing agent solution completely covers a surface of the quantum dot layer, and cleaning remaining reactants on the surface of the quantum dot layer after an oxidation reaction is completed.

9. The method according to claim 8, wherein in the oxidation reaction, time of the oxidation reaction ranges from 20 min to 40 min.

10. The method according to claim 1, wherein the step of providing the substrate having the quantum dot layer on the anode comprises: applying a quantum dot solution on the anode by a solution method, and forming the quantum dot layer after heat treatment, the quantum dot solution comprises a quantum dot and a non-polar solvent.

11. A QLED device, wherein the QLED device comprises an anode, a cathode, and a stacked layer disposed between the cathode and the anode, the stacked layer comprises a quantum dot layer and an electron transport layer, the quantum dot layer is disposed close to the anode, the electron transport layer is disposed close to the cathode, material of the electron transport layer comprises a n-type nano-metal oxide, material of the quantum dot layer comprises a quantum dot, and there is a quantum dot bonded to a dicarboxylic acid ligand at an interface between the quantum dot layer and the electron transport layer.

12. The QLED device according to claim 11, wherein the dicarboxylic acid ligand is azelaic acid.

13. The QLED device according to claim 11, wherein material of the n-type nano-metal oxide comprises at least one of zinc oxide, titanium dioxide, magnesium oxide, or aluminum oxide.

14. The QLED device according to claim 11, wherein material of the quantum dot comprises at least one of a group II-VI compound, a group III-V compound, or a group I-III-VI compound; the group II-VI compound is selected from at least one of CdSe, CdS, CdTe, ZnSe, ZnS, ZnTe, CdZnS, CdZnSe, CdZnTe, ZnSeS, ZnSeTe, ZnTeS, CdSeS, CdSeTe, CdTeS, CdZnSeS, CdZnSeTe, or CdZnSTe; the group III-V compound is selected from at least one of InP, InAs, GaP, GaAs, GaSb, AlN, AlP, InAsP, InNP, InNSb, GaAlNP, or InAlNP; the group I-III-VI compound is selected from at least one of CuInS₂, CuInSe₂, or AgInS₂.

15. The QLED device according to claim 11, wherein at the interface between the quantum dot layer and the electron transport layer, a mass percentage of the quantum dot bonded to the dicarboxylic acid ligand ranges from 80% to 90% based on a total weight of the material of the quantum dot layer.

16. The QLED device according to claim 11, wherein the QLED device further comprises a hole transport layer disposed between the anode and the quantum dot layer; and
the material of the hole transport layer is selected from poly(9,9-dioctylfluorene-CO—N-(4-butylphenyl)diphenylamine), poly(3-hexylthiophene), poly(9-vinylcarbazole), poly[bis(4-phenyl)(4-butylphenyl)amine], 4,4′,4′-tris(carbazol-9-yl)triphenylamine, or 4,4′-bis(9-carbazolyl)biphenyl.

17. A display device, comprising a QLED device manufactured by a method of manufacturing the QLED device, wherein the method of manufacturing the QLED device comprises steps of:
providing a substrate having a quantum dot layer on an anode;
applying an oxidizing agent solution on the quantum dot layer;
forming an electron transport layer on the quantum dot layer; and
forming a cathode on the electron transport layer to obtain the QLED device, and
wherein material of the quantum dot layer comprises a quantum dot, an unsaturated fatty acid ligand is bonded to a surface of the quantum dot, material of the electron transport layer comprises a n-type nano-metal oxide, and there is a quantum dot bonded to a dicarboxylic acid ligand at an interface between the quantum dot layer and the electron transport layer.

18. The display device according to claim 17, wherein the oxidizing agent solution comprises an oxidizing agent, a catalyst, and an ultra-dry organic solvent; and
wherein the oxidizing agent is selected from peroxyorganic acids; the catalyst is selected from at least one of copper chloride, zinc chloride, or aluminum chloride; and
the ultra-dry organic solvent is selected from ultra-dry ethanol.

19. The display device according to claim 17, wherein the peroxyorganic acid is selected from at least one of m-chloroperoxybenzoic acid, trifluoroperoxyacetic acid, monoperoxymaleic acid, monoperoxyphthalic acid, 3,5-dinitroperoxybenzoic acid, p-nitroperoxybenzoic acid, peroxyformic acid, or peroxybenzoic acid.

20. The display device according to claim 17, wherein the dicarboxylic acid ligand is azelaic acid.
